(19) United States
(12) Patent Application Publication
(10) Pub. No.: US 2025/0316481 A1
(43) Pub. Date: Oct. 9, 2025

(54) SUBSTRATE INCLUDING A PRE-EPITAXIAL STACKING FAULT EXPANSION-STOP LAYER, DEVICES INCLUDING THE SAME, AND PROCESS OF MANUFACTURE

(71) Applicant: Axcelis Technologies, Inc., Beverly, MA (US)

(72) Inventors: Fulvio Mazzamuto, Parma PR (IT); Atul Gupta, Lexington, MA (US); Giovanni Franco, Viagrande (IT)

(21) Appl. No.: 19/098,092

(22) Filed: Apr. 2, 2025

Related U.S. Application Data
(60) Provisional application No. 63/573,659, filed on Apr. 3, 2024.

(51) Int. Cl. H01L 21/225; H01L 21/02

(52) U.S. Cl. CPC H01L 21/2251; H01L 21/02447

(57) ABSTRACT

A semiconductor substrate including an epitaxial layer thereon includes a buffer layer of ions formed in the substrate at a depth proximate to an interface between the substrate upper surface and the epitaxial layer provided thereon. The buffer layer defines a pre-epitaxial stack fault expansion-stop layer, wherein the ion implanted buffer layer reduces and modulates thermoelectric stresses proximate to the substrate surface, which inhibits formation and glide of crystallographic defects in and through the substrate that may have been present in the semiconductor substrate as a function of the manufacturing process. Also disclosed are processes for forming the buffer layer in the semiconductor substrate.

### CROSS REFERENCE TO RELATED APPLICATION

The present application claims the benefit of U.S. Application No. 63/573,659, filed Apr. 3, 2024, which is incorporated by reference in its entirety herein.

### FIELD

The present disclosure generally relates to a substrate including a pre-epitaxial stack fault expansion-stop layer, devices including the same, and process of manufacture, and more specifically, to formation of a buffer layer in the substrate using engineered ion implantation prior to epitaxial layer deposition, wherein the ion implanted buffer layer modulates thermoelectric stresses proximate to the substrate surface, which inhibits formation and glide of crystallographic defects in and through the substrate and the subsequently deposited epitaxial layer.

### BACKGROUND

Semiconductor substrates are typically formed of silicon or a compound of two or more elements that serves as a base for the fabrication of electronic devices. The substrate supports the microelectronic or photonic elements that are built in and upon it. Different parts of the semiconducting material are utilized to make the device itself by modifying the localized electronic properties of the semiconductor material through doping and patterning processes. In some devices such as power devices, the entire substrate constitutes the device as the current flows between the contacts/connections located on both the top and bottom of the semiconductor substrate. The substrate is often referred to as a wafer, slice, or base.

Silicon carbide (SiC) can be utilized as the semiconductor substrate, recognized by those familiar with materials science, electronics and physics as being advantageous for its wide band gap properties and also for its extreme hardness, high thermal conductivity, oxidative properties, high electron saturated drift velocity, high electric critical field, and chemical inert properties, among others. These properties make SiC a very attractive semiconductor for fabrication of power semiconductor devices, enabling power density and performance enhancement over devices made from more common materials like silicon.

The most common forms of SiC consist of cubic or hexagonal arrangements of atoms. The stacking of Si and C layers can take on many forms, known as polytypes. The type of SiC crystal is denoted by a number denoting the number of repeat units in the stacking sequence followed by a letter representing the crystalline format, e.g., X C—SiC, wherein X is the number of repeat units. For example, the 3 C—SiC polytype refers to a repeat unit of 3 and a cubic (C) lattice, while a 4 H—SiC polytype refers to repeat unit of 4 and a hexagonal (H) lattice. The different silicon carbide polytypes have some variations in materials properties, most notably electrical properties. The 4 H—SiC polytype has the relatively larger bandgap while the 3 C—SiC has a smaller bandgap, with the bandgaps for most other polytypes falling in between. For high performance power device applications when the bandgap is larger, the material is more capable, in theory, to offer relatively higher power and thermal conductivity performance.

SiC crystals do not occur in nature and as such must be synthesized. Growth of SiC crystals can be executed by sublimation/physical vapor transport (PVT) or chemical vapor deposition. One of the inherent problems in the formation of silicon or a compound of two or more elements such as SiC substrates, is the presence of defects, which, in some instances, cannot be removed completely in current manufacturing processes.

As device geometries shrink and the need for a defect-free surface increases, epitaxy is an increasingly critical step during microelectronic processing, which generally refers to a method to grow or deposit monocrystalline films on a surface of a semiconductor substrate. The defects manifested by the epitaxial growth are also an important concern. More specifically, epitaxial layer stacking faults can occur, which can be detrimental to device performance and the cause of many bright points and bright column failures in charge-coupled devices. In the case of SiC, stacking faults are easier to form and expand relative to silicon because SiC has about 10 times lower energy formation. SiC structures may contain both extended and point defects that can perturb the lattice periodicity. Such defects can evolve and expand during device operation and affect device reliability, which is dependent on the number of stacking faults and their extension from top to bottom contact. Despite significant improvements made in SiC crystal growth techniques during the past years, the number of crystallographic defects still remains an important problem. It was shown that extended defects like stacking faults (SFs), micropipes, screw dislocations and basal plane dislocations play a critical role in the performance degradation and reliability of SiC power devices. Multiple steps may contribute to structural defect degradation. For example, during substrate manufacturing (wiring to polish), sub-surface defects (SSD) may remain impacting subsequent manufacturing steps including epitaxial growth processes. SSD and any substrate defects can glide, evolve and multiplicate during epitaxial growth with some materials and methods of manufacture more prone to the presence of defects than others. Moreover, defects can form, glide and evolve during high thermal budget processes such as during furnace annealing. Still further, during operation, defects can be generated/glide in a phenomenon called bipolar degradation and/or active gate oxide premature failure, degradation).

### BRIEF SUMMARY

Disclosed herein are processes for mitigating expansion of stacking fault defects during manufacture and/or device operation from extending through a substrate and an epitaxial layer formed on the substrate. Also disclosed are semiconductor substrates including an ion implanted buffer layer proximate to an upper surface of the substrate, and devices including the same.

In one or more embodiments, the process for mitigating expansion of stacking fault defects from extending from a substrate to an epitaxial layer formed on substrate includes implanting ions into the substrate below an upper surface thereof to form a buffer layer of a defined thickness; epitaxially growing the epitaxial layer on the substrate; and further processing to form a device; wherein the buffer layer inhibits formation and glide of crystallographic defects in the substrate and the epitaxial layer relative to a substrate and epitaxial layer free of a buffer layer in the substrate. Such expansion of defects between the substrate and epitaxial layer may occur during growth of the layer or during device operation at high current densities which is a significant reliability concern for the use of these devices.

In one or more embodiments, the semiconductor substrate including an epitaxial layer thereon includes a buffer layer (that contains a higher doping level/carrier concentration than the epitaxial layer in the substrate at a depth proximate to an interface between the substrate upper surface and the epitaxial layer provided thereon.

These and other objects, advantages and features of the disclosure will become better understood from the detailed description of the disclosure that is described in conjunction with the accompanying drawings.

### BRIEF DESCRIPTION OF DRAWINGS

FIG. 1 is a prior art block diagram and schematic diagram of an exemplary epitaxial growth process on a silicon carbide substrate; and

FIG. 2 is a prior art block diagram and schematic diagram of an epitaxial growth process on a silicon carbide substrate in accordance with one example of the present disclosure.

### DETAILED DESCRIPTION

The present disclosure is generally directed to a substrate including a pre-epitaxial stack fault expansion-stop layer and process of manufacture, and more specifically, to formation of a buffer layer in the substrate using engineered ion implantation prior to epitaxial layer deposition, wherein the ion implanted buffer layer inhibits formation and glide of crystallographic defects in and through the substrate and the subsequently deposited epitaxial layer. Advantageously, the presence of the buffer layer in the substrate mitigates propagation and/or eliminates defect formation that may occur upon epitaxial deposition of a layer onto the substrate and/or during device operation, which can occur due to bipolar degradation in high current devices.

In the present disclosure, reference will be made to silicon carbide substrates, wherein current manufacturing processes to form the silicon carbide substrate are more prone to the presence of defects than other materials such as silicon. However, it should be noted that the particular substrate is not intended to be limited and can include silicon, gallium arsenide, silicon carbide, indium phosphide, and the like.

For the purposes of the description hereinafter, the terms “upper”, “lower”, “top”, “bottom”, “left,” and “right,” and derivatives thereof shall relate to the described structures, as they are oriented in the drawing figures. The same numbers in the various figures can refer to the same structural component or part thereof. Additionally, the articles “a” and “an” preceding an element or component are intended to be nonrestrictive regarding the number of instances (i.e., occurrences) of the element or component. Therefore, “a” or “an” should be read to include one or at least one, and the singular word form of the element or component also includes the plural unless the number is obviously meant to be singular.

Spatially relative terms, e.g., “beneath,” “below,” “lower,” “above,” “upper,” and the like, can be used herein for ease of description to describe one element or feature's relationship to another element(s) or feature(s) as illustrated in the figures.

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

As used herein, the term “about” modifying the quantity of an ingredient, component, or reactant of the disclosure employed refers to variation in the numerical quantity that can occur, for example, through typical measuring procedures used for making component mixtures. Furthermore, variation can occur from inadvertent error in measuring procedures, differences in the manufacture, source, or purity of the ingredients employed to make the compositions or carry out the methods, and the like.

It will also be understood that when an element, such as a layer, region, or substrate is referred to as being “on” or “over” another element, it can be directly on the other element or intervening elements can also be present. In contrast, when an element is referred to as being “directly on” or “directly over” another element, there are no intervening elements present, and the element is in contact with another element.

The ion implantation system and ion implantation processes in accordance with the present disclosure are not intended to be limited provided the precursor compositions can be appropriately heated, vaporized, or etched when exposed to a suitable plasma source, and have ions extracted therefrom. Accordingly, the present disclosure will now be described with reference to the drawings, wherein like reference numerals may be used to refer to like elements throughout. It is to be understood that the description of these aspects are merely illustrative and that they should not be interpreted in a limiting sense. In the following description, for purposes of explanation, numerous specific details are set forth in order to provide a thorough understanding of the present invention. It will be evident to one skilled in the art, however, that the present disclosure may be practiced without these specific details. Further, the scope of the disclosure is not intended to be limited by the embodiments or examples described hereinafter with reference to the accompanying drawings but is intended to be only limited by the appended claims and equivalents thereof.

It is also noted that the drawings are provided to give an illustration of some aspects of embodiments of the present disclosure and therefore are to be regarded as schematic only. In particular, the elements shown in the drawings are not necessarily to scale with each other, and the placement of various elements in the drawings is chosen to provide a clear understanding of the respective embodiment and is not to be construed as necessarily being a representation of the actual relative locations of the various components in implementations according to an embodiment of the invention. Furthermore, the features of the various embodiments and examples described herein may be combined with each other unless specifically noted otherwise.

It is also to be understood that in the following description, any direct connection or coupling between functional blocks, devices, components, circuit elements or other physical or functional units shown in the drawings or described herein could also be implemented by an indirect connection or coupling.

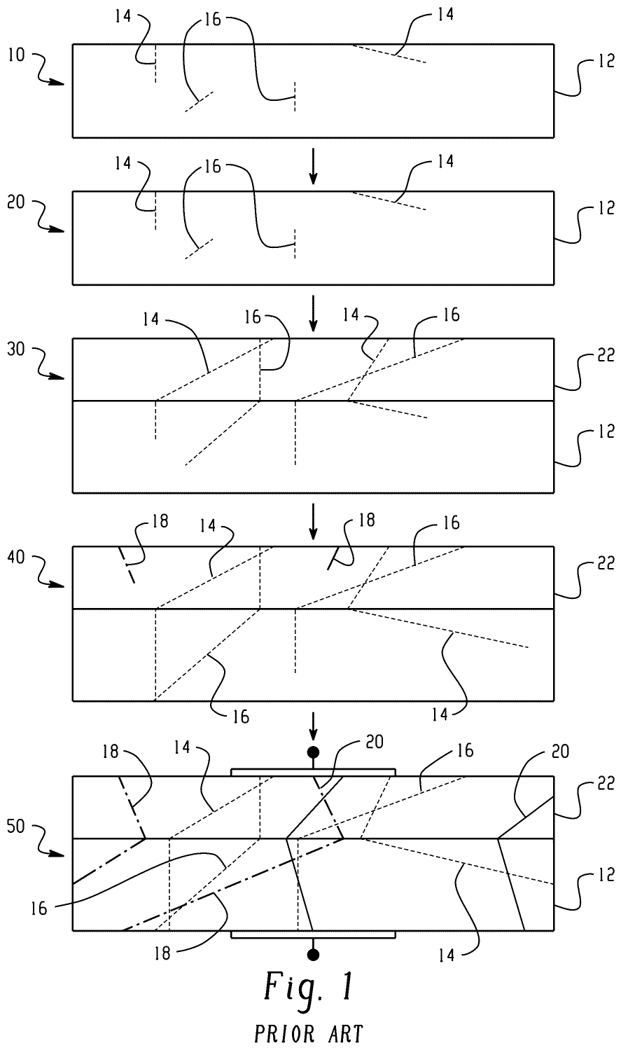

As shown in step 10 of prior art FIG. 1, sub-surface defects (SSD) 14 at the surface and substrate defects 16 below the surface can occur in the manufacturing processes of a semiconductor substrate 12, which oftentimes cannot be entirely prevented during current manufacturing processes as in the case of silicon carbide. As used herein, SSD generally refer to defects at the surface, which can typically arise during surface polishing, e.g., CMP, sawing, grinding, or the like processes. In contrast, substrate defects are those within the body of the substrate and can occur during the manufacture of the substrate itself. These defects are known to glide, evolve and/or multiply during subsequent processing, which can cause stacking faults during epitaxial growth on the substrate 12.

Referring to silicon carbide substrates as an example, step 20 of FIG. 1, the uppermost surface of the silicon carbide substrate is first cleaned in preparation for epitaxial deposition, which generally includes the removal of any particles, metal ions, and organic substances thereon. The cleaning process is typically a wet cleaning process using chemical solvents with strong corrosive and oxidizing properties, such as H₂SO₄, H₂O₂, dihydrofuran, NH₃·H₂O, and the like. The impurity particles on the surface can react with the solvent to form soluble substances and gases. In order to improve the cleaning effect, it is possible to use mega-acoustic, heating, vacuum and other technical means, and finally use ultra-pure water to clean the surface of the silicon wafer to obtain a silicon wafer that meets the cleanliness requirements. An exemplary wet cleaning process for cleaning SiC substrates includes an SC1 process (treatment with dilute aqueous ammonia and hydrogen peroxide solution at about 75-80° C.), rinse with deionized water, treatment with dilute aqueous hydrofluoric acid (HF) or hydrochloric acid (HCl) and hydrogen peroxide solution, rinse with deionized water, followed by drying the substrate. Depending on the parameters of the wet cleaning process, defects can form, glide, and continue to evolve in the substrate.

In step 30, an epitaxial layer 22 is deposited onto the surface of the substrate 12. The epitaxial layer, also referred to as an epi-layer, is a crystalline layer, usually grown or deposited onto the substrate. The two most common methods used for epitaxy growth are chemical vapor deposition, CVD, or molecular beam epitaxy (MBE). Differing from the Czochralski silicon growth process, epitaxy can be grown below the melting point using CVD and MBE.

The epitaxy process of growing a SiC layer on a SiC substrate generally includes heating the substrate, in situ etching of the substrate surface, epitaxial growth of the SiC layer on the etched surface followed by cooling. Various gases such as H₂, HCl/H₂, hydrocarbon/H₂, chlorosilanes, halocarbons, or SiH₄/H₂ are often used during the process. The epitaxy will grow in the same crystal orientation as the substrate, and the growth rate is a function of the epitaxial temperature as well as the concentration of the gaseous elements. Epitaxial temperatures can vary and can be as high as about 1700° C. for an extended period of time and at relatively low pressure. Epitaxial film thicknesses can range from about 1 to 200 μm, depending on the device application.

By way of example, a SiC layer can be epitaxially grown by first placing the SiC substrate in a growth furnace, evacuating the furnace, and adjusting the pressure to about 1×10⁴ to about 3×10⁴ Pa by introducing thereinto, for example, a hydrogen gas. The temperature in the growth furnace may be raised, while keeping the pressure constant. When the temperature reaches a growth temperature, raw material gases for providing a silicon source and a carbon source, e.g., SiH₄ gas and C₂H₄ gas, may be introduced to start the growth. The temperature is generally maintained, or modulated depending on the process, until a desired thickness is epitaxially grown. The flow of the source gases into the furnace is terminated and the temperature decreased, for example, while flowing only the hydrogen gas.

As shown in step 30 of prior art FIG. 1, the sub-surface defects 14 in the SiC substrate 12 are transferred into the SiC epitaxial layer 22, i.e., the existing bulk stacking fault defects glide freely into the epitaxial layer. Moreover, during processing, the substrate defects 16 can evolve and propagate into the epitaxial layer 22 as shown.

Subsequent to epitaxial growth, the substrate 12 including the epitaxial layer 22 can be subjected to numerous process steps including, but not limited to, lithographic patterning, deposition of metals and dielectrics, junction formation, dopant implantation, furnace annealing, and the like. In the case of annealing, the temperatures can be relatively high depending on the substrate. For example, SiC is typically annealed at about 1700 to 2000° C. for a defined period of time of a few minutes. Annealing is generally utilized to remove any residual hydrogen, if present, and improve the structure by reducing high dislocation densities or small pits. As shown in step 40 of FIG. 1, the effect of furnace annealing at an elevated temperatures for prolonged periods of time can result in additional stacking fault defects 18 as well as increase the existing stacking faults glide as shown. Again, as noted above, if the number of stacking faults exceed a critical number, then the resulting devices can fail.

Moreover, as shown in step 50, when the desired device is fabricated and operational in SiC bipolar devices, additional defects 20 can be generated and glide in a phenomenon generally known as bipolar degradation. Bipolar degradation can generally by triggered by forward current flow as low as 100 A/cm² and temperature stress in SiC bipolar devices, including MOSFET, Igbt, Superjunction, and JFET body diodes. The bipolar degradation can affect the long-term reliability and performance.

In the present disclosure, formation of a pre-epitaxial buffer layer in the substrate using engineered ion implantation can prevent stacking fault by inhibiting stacking fault glide existing and/or formed in the subsequent process steps. The presence of the buffer layer modulates the thermoelastic stresses close the surface of the substrate.

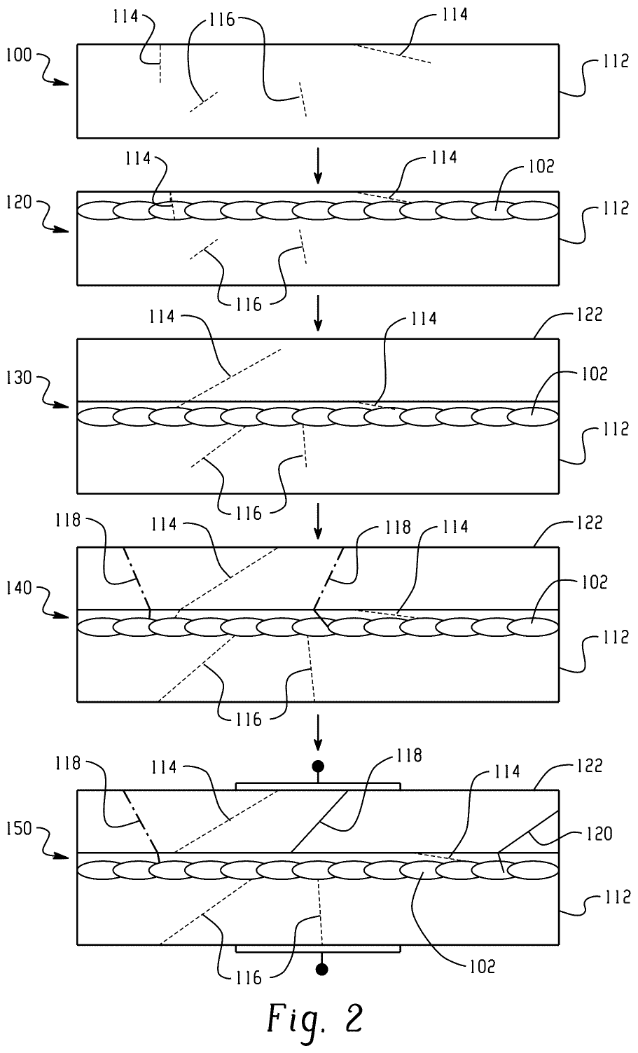

Referring now to FIG. 2, there are shown various steps for forming a substrate including the buffer layer. In step 100, the substrate 112 is manufactured, which can include sub-surface defects (SSD) 114 at the surface and substrate defects 16 below the surface.

In step 120 of FIG. 2, a buffer layer 102 is formed near the uppermost surface of substrate 112 by implanting ions that effectively influence the lattice structure of the substrate 112 and act as a defect expansion barrier while avoiding a significant reduction of resistivity in the substrate. The buffer layer 102 has been found to modulate the thermoelastic stress close to the surface, inhibiting formation and glide of crystallographic defects in and through the substrate 112. In one or more embodiments, the ions can be implanted at the depth of about 10 nanometers (nm) to about 5000 nm addressable from 1 kiloelectron volts (keV) to 20 megaelectron volts (MeV). The implant can be single or a chain of implant to form a thicker implanted layer with a plateau profile, for example. Moreover, it should be apparent that the angle of implant is not intended to be limited. The implant can be performed with or without a precise angle to channel the ion implantation and obtain a precise profile and implant defect level. Still further, the implant can be performed from about room temperature to about 700° C. In one or more embodiments, the implant is performed at an elevated temperature such as about 400° C. or higher so as to reduce the implant induced defects.

The thickness of the buffer layer is not intended to be limited and an generally range from about a few tens of nanometers to about 1 microns.

By implanting the substrate 112 to form a buffer layer of implanted ions, defect expansion can be effectively blocked to neutralize SSD as will be described in subsequent processing steps. However, care must be taken to minimize surface damage during ion implantation to preserve the quality of surface for effective epitaxial seed growth.

The particular implanted ion species are not intended to be limited. In one or more embodiments, the ion species can include n-type dopants such as phosphorous or nitrogen, p-type dopants such as aluminum or boron, neutral species from Group XIV of the periodic table, e.g., silicon, carbon; germanium, and small mass ions such as hydrogen and helium, or other inert species.

In one or more embodiments, implantation of the buffer layer 102 occurs prior to the pre-epitaxial cleaning step, which as previously described is typically a wet clean process configured to remove hydrogen, particles, and any organic residues on the surface of the substrate. By forming the buffer layer 102 prior to epitaxial deposition, standard ion implantation equipment can advantageously be used.

As shown in step 130 of FIG. 2, once the substrate surface has been cleaned, epitaxial deposition of layer 122 is formed on the substrate 102. The presence of the buffer layer prevents and/or minimizes further glide propagation of the SSD 114 and substrate defects 116 through the buffer layer 102 as shown.

Moreover, as shown in step 140 of FIG. 2, the presence of the buffer layer prevents, inhibits and/or minimizes further glide propagation of the SSD 114 and substrate defects 116 in and through the buffer layer 102 that can result during junction formation, implantation of dopant ions and annealing. As a result, stacking fault expansion from top to bottom, which would normally cause device degradation, is inhibited and prevented. Additional defects 118 can be formed in the epitaxially deposited layer or the substrate by these subsequent processes but expansion does not occur through the buffer layer because of the reduction in thermoelectric stresses caused by the ion implantation to form the buffer layer.

Likewise, during operation of the device as shown in step 150 of FIG. 2, expansion through the buffer layer 102, which functions as an expansion stop layer. The pre-existing SSD 114, substrate defects 116, epitaxial layer defects 118 and any new defects 120 such as bipolar degradation defects caused by operating the device are inhibited from propagating through the buffer layer, thereby preventing expansion of these defects from the top of the epitaxially layer 122 to the bottom of the substrate 102 as would commonly occur in the absence of the buffer layer 102.

The foregoing descriptions of the preferred embodiments of the disclosure have been presented for purposes of illustration and description. It is not intended to be exhaustive or to limit the disclosure to the precise forms disclosed. Obvious modifications or variations are possible in light of the above teachings. The embodiments were chosen and described to provide the best illustration of the principles of the disclosure and its practical applications to thereby enable one of ordinary skill in the art to utilize the disclosure in various embodiments and with various modifications as are suited to the particular use contemplated. All such modifications and variations are within the scope of the disclosure as determined by the appended claims when interpreted in accordance with the breadth to which they are fairly, legally and equitably entitled.

What is claimed:

1. A process for minimizing stacking fault defects from extending from a substrate to an epitaxial layer deposited on the substrate, the process comprising:
implanting ions into the substrate below an upper surface thereof to form a buffer layer of a defined thickness;
epitaxially growing the epitaxial layer on the substrate; and
further processing to form a device; wherein the buffer layer inhibits formation and glide of crystallographic defects in the substrate and the epitaxial layer relative to the substrate and epitaxial layer free of the buffer layer in the substrate.

2. The process of claim 1, wherein the implanted buffer layer relative to the upper surface of the substrate is at a depth of about 10 nanometers (nm) to about 5000 nm.

3. The process of claim 1, wherein the substrate is silicon, gallium arsenide, silicon carbide, gallium nitride or indium phosphide.

4. The process of claim 1, wherein the substrate is silicon carbide.

5. The process of claim 1, wherein implanting the ions to form the implanted buffer layer is at a temperature ranging from room temperature to 700° C.

6. The process of claim 1, wherein implanting the ions to form the implanted buffer layer is at a temperature greater than 400° C.

7. The process of claim 1, wherein implanting the ions to form the implanted buffer layer is a single ion implantation step.

8. The process of claim 7, wherein implanting the ions to form the implanted buffer layer is a chain of implantation process steps comprising one or more ion species.

9. The process of claim 1, wherein implanting the ions is at a precise angle.

10. The process of claim 1, wherein the implanted buffer layer has a plateau profile.

11. The process of claim 1, wherein implanting the ions comprises implanting at least one of an o-type dopant, a p-type dopant, a neutral species selected from Group XIV of the periodic table, hydrogen or helium.

12. A semiconductor substrate including an epitaxial layer thereon, the semiconductor substrate comprising an implanted buffer layer of ions formed in the substrate at a depth proximate to an interface between the substrate upper surface and the epitaxial layer provided thereon.

13. The semiconductor substrate of claim 14, wherein the semiconductor substrate is silicon carbide and comprises one or more sub-surface defects and/or one or more substrate defects; wherein the one or more sub-surface defects and/or one or more substrate defects do not extend through the implanted buffer layer during formation of a device formed with the semiconductor substrate and epitaxial layer.

14. The semiconductor substrate of claim 14, wherein the implanted buffer layer relative to substrate upper surface is at a depth of about 50 nanometers (nm) to about 500 nm.

15. The semiconductor substrate of claim 14, wherein the implanted ions comprise an n-type dopant. a neutral species selected from Group XIV of the periodic table, hydrogen or helium.

16. The semiconductor substrate of claim 18, wherein the n-type dopant is phosphorous or nitrogen.

17. The semiconductor substrate of claim 18, wherein the neutral species selected from Group XIV of the periodic table is silicon or carbon.

18. A device comprising a semiconductor substrate including an epitaxial layer thereon, the semiconductor substrate comprising an implanted buffer layer of ions formed in the substrate at a depth proximate to an interface between the substrate upper surface and the epitaxial layer provided thereon.

19. The device of claim 18, wherein the semiconductor substrate is silicon carbide and comprises one or more sub-surface defects and/or one or more substrate defects; wherein the one or more sub-surface defects and/or one or more substrate defects do not extend through the implanted buffer layer during formation of the device or operation of the device.

20. The device of claim 18, wherein the implanted buffer layer comprises at least one of an n-type dopant, a p-type dopant, a neutral species selected from Group XIV of the periodic table, hydrogen or helium.
